(19) United States
(12) Patent Application Publication
(10) Pub. No.: US 2025/0266257 A1
(43) Pub. Date: Aug. 21, 2025

(54) CYCLIC GROWTH PROCESSES

(71) Applicant: Applied Materials, Inc., Santa Clara, CA (US)

(72) Inventors: Hansel LO, San Jose, CA (US); Christopher S. OLSEN, Fremont, CA (US); Sameh HELMY, Santa Clara, CA (US)

(21) Appl. No.: 18/442,679

(22) Filed: Feb. 15, 2024

(51) Int. Cl. H01L 21/02; H01J 37/32

(52) U.S. Cl. CPC H01L 21/0223; H01J 37/32357; H01L 21/0214; H01L 21/02164; H01J 2237/332; H01J 2237/338

(57) ABSTRACT

The disclosure provides a system and methods of performing a cyclic growth oxidation process. The method includes forming a plasma of a plasma gas using a remote plasma source fluidly coupled to a conduit coupled to a first nozzle of a processing chamber. An oxidation radical is produced. A first oxidation process is performed by introducing the oxidation radical for a first period of time to the processing chamber using the first nozzle. A bake process is performed for a second period of time. A second oxidation process is performed by introducing the oxidation radical for a third period of time.

### BACKGROUND

### Field

Embodiments of the present disclosure generally relate to a process chamber for processing a substrate, and related methods.

### Description of the Related Art

In the processing of substrates, such as semiconducting substrates, the substrate is placed on a support in a process chamber and suitable processing conditions are maintained in the process chamber. For example, the substrate can be oxidized in a controlled oxidation process to chemically process the substrate. The substrate can be oxidized, for example, by an array of chemicals disposed above and/or below the substrate in the chamber. Oxidation processing can be used, for example, to oxidize silicon nitride to a silicon oxide or oxynitride.

It has been observed that variations in oxidation processes across the substrate can result in non-uniform oxidation of the substrate, e.g., reduced conformality. Conventionally, attempts to increase conformality have focused on slow oxidation processes to produce an oxide film. Unfortunately, decreased oxidation times reduces throughput, requiring longer processing time to produce thicker films. This is further complicated as the increased processing time of the oxidation process can lead to reduced conformality in thicker films.

Accordingly, improved methods of and apparatuses for oxidation processes are needed.

### SUMMARY

In an aspect, the disclosure provides a method of performing a cyclic growth oxidation process. The method includes forming a plasma of a plasma gas using a remote plasma source fluidly coupled to a conduit coupled to a first nozzle of a processing chamber. An oxidation radical is produced. A first oxidation process is performed by introducing the oxidation radical for a first period of time to the processing chamber using the first nozzle. A bake process is performed for a second period of time. A second oxidation process is performed by introducing the oxidation radical for a third period of time.

In another aspect, the present disclosure provides a substrate processing system. The system including a processing chamber. A conduit is coupled to a first nozzle of the processing chamber. A remote plasma source is fluidly coupled to the conduit. The remote plasma source is fluidly coupled to a first gas source. A controlled is configured to form a plasma of a plasma gas using the remote plasma source fluidly coupled to the conduit, produce an oxidation radical using the first gas source, perform a first oxidation process by introducing the oxidation radical for a first period of time to the processing chamber using the first nozzle, perform a bake process perform a bake process for a second period of time by introducing a bake gas to the processing chamber using the first nozzle, and perform a second oxidation process by introducing the oxidation radical for a third period of time to the processing chamber using the first nozzle.

In another aspect the present disclosure provides a computer readable medium. The computer readable medium configured to form a plasma of a plasma gas using a remote plasma source fluidly coupled to a conduit coupled to a first nozzle of a processing chamber, produce an oxidation radical using a first gas, perform a first oxidation process by introducing the oxidation radical for a first period of time to the processing chamber using the first nozzle, perform a bake process for a second period of time by introducing a bake gas to the processing chamber using the first nozzle and increasing a temperature of the processing chamber, and perform a second oxidation process by introducing the oxidation radical for a third period of time to the processing chamber using the first nozzle.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1A is a schematic cross-sectional view of a process chamber, according to embodiments of the present disclosure.

FIG. 1B is a schematic cross-sectional view of a gas injection assembly shown, according to embodiments of the present disclosure.

FIG. 1C is a schematic cross-sectional view of an orifice of a gas injection assembly, according to embodiments of the present disclosure.

FIG. 2 is a schematic cross-sectional view of a portion of a gas injection assembly, according to embodiments of the present disclosure.

FIG. 3 is a schematic cross-sectional view of a portion of a gas injection assembly, according to embodiments of the present disclosure.

FIG. 4 is a diagrammatic representation of a method of remote plasma oxidation, according to embodiments of the disclosure.

FIG. 5A shows a temperature over time graph of a method of remote plasma oxidation, according to embodiments of the disclosure.

FIG. 5B shows an oxidation radical flow over time graph of a method of remote plasma oxidation, according to embodiments of the disclosure.

FIG. 5C shows a bake gas over time graph of a method of remote plasma oxidation, according to embodiments of the disclosure.

FIG. 6 is a graph showing a conformality of a standard oxidation process compared to a cyclic growth process, according to embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure provides a system and method for performing a cyclic growth oxidation process can improve conformality and thickness of an oxide layer formed in a memory hole of a substrate having a high aspect ratio. In certain embodiments, the system and method can reduce the throughput processing time of oxidation processes by improving one or more memory holes prior to subsequent oxidations by reducing a surface property, e.g., sticking coefficient, roughness, concentration of contaminants. By reducing a surface property, the oxide layer may uniformly form on the substrate surface, increasing conformality.

### Processing Chamber

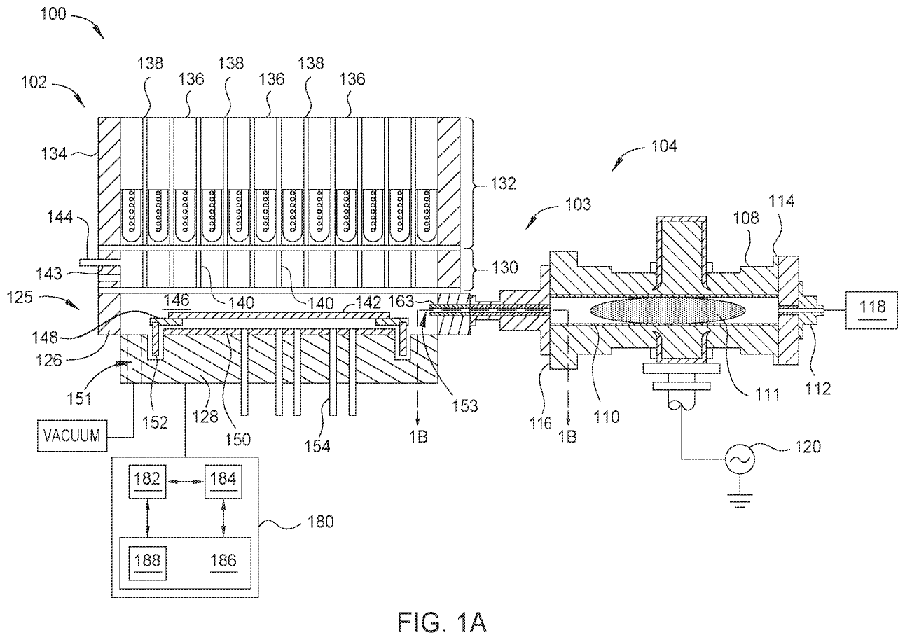

FIG. 1A is a schematic cross-sectional view of a processing chamber, according to one embodiment. The processing system 100 includes a process chamber 102, a remote plasma source (RPS) 104, and a gas injection assembly 103 coupling the RPS 104 to the process chamber 102. Herein, the process chamber 102 is a rapid thermal processing (RTP) chamber, such as a rapid thermal anneal (RTA) chamber. In other embodiments, the process chamber 102 is any other process chamber where delivery of at least metastable radical molecular species and/or radical atomic species to a processing volume is desired, e.g., a furnace. In an embodiment, a furnace includes a volume of about 50 wfs by 10 mm/wf×π150 mm², e.g., about 30 liters to about 50 liters. For example, in other embodiments the process chamber is plasma enhanced or plasma assisted deposition chamber, such as a plasma-enhanced chemical vapor deposition (PECVD) chamber or a plasma-enhanced atomic layer deposition chamber (PEALD).

A controller 180 coupled to the processing system 100 is used to control the operation of the process chamber 102, the RPS 104, and the gas flow into the gas injection assembly 103. The controller 180 generally includes a central processing unit (CPU) 182, a memory 186, and support circuits 184 for the CPU 182. The controller 180 may control the processing system 100 directly, or via other computers and/or controllers (not shown) coupled to the process chamber 102, the RPS 104, and/or the gas injection assembly 103 such that a rate of gas flow from the RPS 104 is controlled as the gas flow from the RPS 104 enters both the gas injection assembly 103 and the process chamber 102.

The controller 180 described herein is any form of a general-purpose computer processor that is used in an industrial setting for controlling various chambers and sub-processors thereon or therein. The memory 186, or computer readable medium, is one or more of readily available memory such as random access memory (RAM), read only memory (ROM), floppy disk, hard disk, flash drive, or any other form of digital storage, local or remote. The support circuits 184 are coupled to the CPU 182 for supporting the processor in a conventional manner. The support circuits 184 can include cache, power supplies, clock circuits, or input/output circuitry and subsystems. In one example, substrate processing parameters are stored in the memory 186 as a software routine 188 that is executed or invoked to turn the controller 180 into a specific purpose controller to control the operations of the processing system 100. The controller 180 is configured to perform any of the methods described herein.

The process chamber 102 includes a chamber base 125, a lamp assembly 132, and a window assembly 130 coupled to the lamp assembly 132. The chamber base 125 includes a base wall 128 and one or more first sidewalls 126. The base wall 128, the one or more first sidewalls 126, and the window assembly 130 define a processing volume 146. The window assembly 130 is disposed between the processing volume 146 and the lamp assembly 132. Herein, the lamp assembly 132, enclosed by one or more second sidewalls 134, includes a plurality of lamps 136 each disposed in a respective tube 138. The window assembly 130 includes a plurality of light pipes 140, where each of the plurality of light pipes 140 is aligned with a respective tube 138 of the lamp assembly 132 so that the radiant thermal energy provided by the plurality of lamps 136 is directed to a substrate 142 disposed in the processing volume 146.

In some embodiments, one or more respective volumes in the plurality of light pipes 140 are maintained at sub-atmospheric conditions using one or more vacuum exhaust pumps (not shown) in fluid communication therewith through an opening 144 formed in one of the one or more second sidewalls 134. In some embodiments, the window assembly 130 further includes a conduit 143 disposed therein for circulating a cooling fluid from a cooling fluid source (not shown) between the plurality of light pipes 140. Herein, the processing volume 146 is fluidly coupled (connected) to a chamber exhaust, such as to one or more dedicated vacuum pumps, through one or more exhaust ports 151. The chamber exhaust maintains the processing volume 146 at sub-atmospheric conditions and evacuates processing and other gases therefrom.

### Substrate Support

A support ring 148 disposed in the processing volume 146 is used to support a substrate 142 during the processing thereof. The support ring 148 is coupled to a rotatable cylinder 152 which is used to rotate the support ring 148 about a vertical axis thereof to facilitate uniform heating of the substrate 142. In some embodiments, the rotatable cylinder 152 is levitated and rotated by a magnetic levitation system (not shown). A reflector plate 150 disposed on the base wall 128 in the processing volume 146 is used to reflect energy to a non-device surface of the substrate 142 to further facilitate uniform heating of the substrate 142. One or more temperature sensors, such as pyrometers 154 disposed through the base wall 128 and further disposed through the reflector plate 150, are used to monitor the temperature of the substrate 142 during the processing thereof. An activated gas, formed according to embodiments described herein, flows into the processing volume 146 of the process chamber 102 through an inlet port 153, disposed through one of the one or more first sidewalls 126, which is fluidly coupled to the gas injection assembly 103. In some embodiments, the inlet port 153 is defined by a nozzle, such as nozzle 163. Herein, the activated gas comprises molecular and/or atomic species, at least metastable radical molecular and/or radical atomic species, or combinations thereof.

### Plasma

The RPS 104 herein is coupled to a microwave power supply 120 which is used to ignite and maintain a plasma 111 therein. In other embodiments, the RPS 104 comprises an inductively coupled plasma (ICP) source, a transformer coupled plasma (TCP source), or a capacitively coupled plasma (CCP source). In some other embodiments, the RPS is coupled to an RF power supply. The RPS 104 includes an RPS body 108 disposed about a tube 110 in which the plasma 111 is formed. The tube 110 is formed of a dielectric material, such as SiO₂, Al₂O₃, quartz, or combinations thereof. The RPS body 108 includes a first end 114 coupled to an inlet 112 which is in fluid communication with one or more first gas sources 118 and a second end 116, distal from the first end 114, coupled to the gas injection assembly 103. An example gas injection assembly 103 is further described in FIG. 1B.

### Gas Injection Assembly

FIG. 1B is a schematic sectional view of a portion of the gas injection assembly 103 taken along line 1B-1B of FIG. 1A. Herein, the gas injection assembly 103 includes a body 170 formed of a metal, such as stainless steel, a low recombination dielectric liner 173, such as quartz or sapphire, and a first flange 171 to couple the gas injection assembly 103 to one of the one or more sidewalls of a process chamber. The gas injection assembly 103 is coupled to a sidewall such as the one of the one or more first sidewalls 126 of the process chamber 102 described in FIG. 1A. The gas injection assembly further includes a second flange 172 to couple the gas injection assembly 103 to an RPS, such as the RPS 104 described in FIG. 1A, and optionally one or more gas injection ports 174 formed through the body 170 and the liner 173. The gas injection assembly 103 has a length L(1), measured along its longitudinal axis A between a mounting surface plane of the first flange 171 and a mounting surface plane of the second flange 172, where the length L(1) is between about 25 mm and about 150 mm, such as between about 50 mm and about 100 mm, such as between about 75 mm and about 100 mm. However, other dimensions are contemplated.

A plasma 111 formed in the RPS 104 flows into the gas injection assembly 103 where radicals and/or ions, for example oxygen ions, from the plasma can collide with a molecular species of one or more second gases, for example H₂, injected into the internal volume through a carrier conduit (not shown). The radicals and/or ions provided by the plasma 111 have sufficient energy to dissociate the molecular species, through collision therewith, into an activated gas comprising at least metastable radical molecular species and/or radical atomic species, e.g., H· and/or O·.

Each of the one or more gas injection ports 174 comprise an opening formed through the body 170 and further through the liner 173. A diameter D(2) of the one or more gas injection ports 174 is between about 0.5 mm and about 6 mm, such as between about 1 mm and about 6 mm, such as between about 2 mm and about 5 mm, for example between about 2 mm and about 4 mm. However, other dimensions are also contemplated. In some examples, the one or more gas injection ports 174 are located at a distance L(2), as measured along the longitudinal axis A from a mounting surface plane of the first flange 171 to one or more longitudinal axis E of the one or more respective gas injection ports 174. The distance L(2) is between about 20 mm and about 80 mm, such as between about 30 mm and about 60 mm, or less than about 80 mm, such as less than about 60 mm. A longitudinal axis E of the one or more gas injection ports forms an angle ϕ with the longitudinal axis A of the gas injection ports where the angle ϕ is substantially 90°. The angle ϕ is less than about 90° so that the second gas as introduced through the gas injection port 174 is generally flowing in the downstream direction towards the inlet port 153 of the process chamber 102 and not upstream towards the RPS 104. In one example, molecular hydrogen is introduced through the inject ports 174. In such an example, the total concentration of hydrogen within the gas injection assembly 103 may be maintained below 20 atomic percent to reduce damage to the liner 173.

In one example, a longitudinal axis A of the gas injection assembly 103 intersects with a longitudinal axis B of the inlet port 153 (disposed through one of the one or more sidewalls 126 of a process chamber 102) at an angle θ of between about 0° (i.e., co-linear) and about 80°, such as between about 10° and about 70°, such as between about 20° and about 70°, or between about 10° and about 45°, for example between about 20° and about 45°. The longitudinal axis A of the gas injection assembly 103 and a longitudinal axis C of the RPS 104 form an angle α of less than about 45°, such as less than about 30°, such as less than about 20°, for example less than about 10°, or between about 0° and or about 20°, for example between about 10° and about 20°. The longitudinal axis C of the RPS 104 and the longitudinal axis A of the gas injection assembly 103 are substantially co-linear or are substantially parallel. Providing an angle θ, and/or an angle a of more than about 0° promotes recombination of ions with electrons or other charged particles through collision therebetween as the ions lose momentum through collisions when hitting the interior surfaces of the inlet port 153.

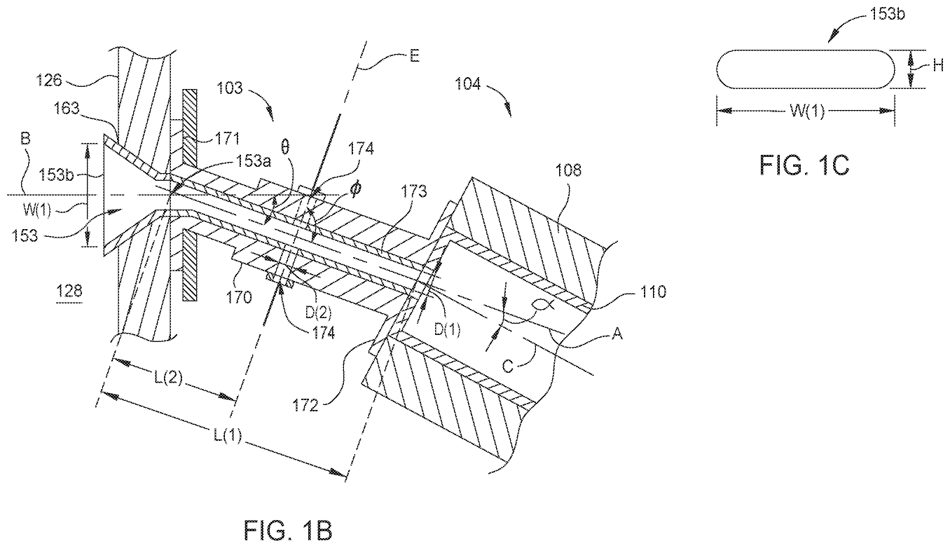

FIG. 2 is a schematic cross-sectional view of a portion of a gas injection assembly 203, according to another embodiment. The gas injection assembly 203 is substantially similar to the gas injection assembly 103 described in FIGS. 1A-1C except that one or more gas injection ports 274 disposed through the body 170 and the liner 173 have a substantially slit (e.g., elongated) cross-sectional shape at a first opening 274a in the liner 173 and a substantially circular cross-sectional shape at a second opening 274b in a surface of the body 170. Herein, the one or more first openings 274a have a length L(3) to width W(2) ratio, of more than 1:1, such as more than 2:1, for example more than about 3:1. The width W(2) may be between about 0.5 mm and about 6 mm, such as between about 1 mm and about 5 mm, for example between about 1 mm and about 4 mm. The one or more first openings 274a of the one or more gas injection ports 274 are substantially parallel, along a length L(3), to the longitudinal axis A of the gas injection assembly 203. The one or more first openings 274a of the one or more gas injection ports 274 may be substantially orthogonal to the longitudinal axis A along a length L(3). The first openings 274a of the one or more gas injection ports 274 may be of any other orientation to the longitudinal axis A. The cross-sectional shape of the gas injection port 274 gradually changes from a substantially circular cross-sectional shape (orthogonal to the longitudinal axis E) at the second opening 274b to the substantially slit cross-sectional shape at the first opening 274a to direct gas flow therethrough to ribbon like flow. The one or more gas injection ports 274 may maintain a substantially slit cross-sectional shape from the second opening 274b to the first opening 274a and substantially the same cross-sectional opening area therethrough.

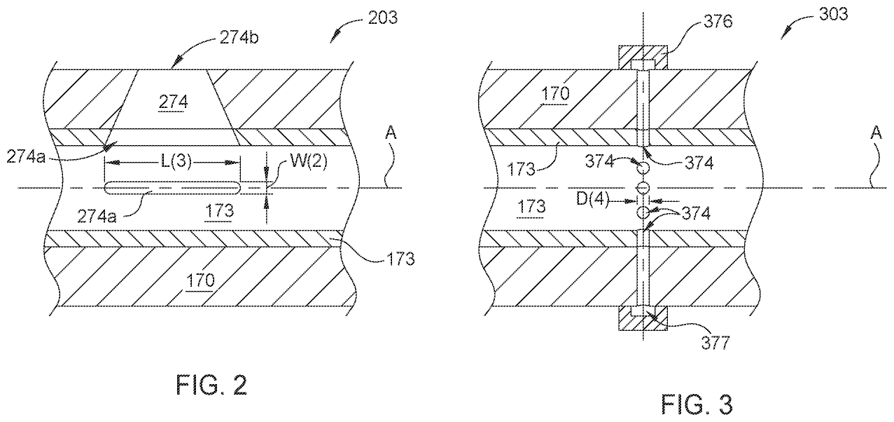

FIG. 3 is a schematic cross-sectional view of a portion of a gas injection assembly 303, according to another embodiment. The gas injection assembly 303 is substantially similar to the gas injection assembly 103 described in FIGS. 1A-1C except that processing gases are delivered through a plurality of openings 374 formed through the liner 173 and the body 170, where the plurality of openings 374 are in fluid communication with an annular passage 377 disposed in an annular ring 376 coupled to the body 170 and concentrically disposed about a circumference thereof. Each of the plurality of openings 374 have a diameter D(4) between about 0.1 mm and about 5 mm, such as between about 0.5 mm and about 4 mm, or between about 0.5 mm and about 4 mm, for example between about 1 mm and about 4 mm.

### Substrate Memory Hole

A substrate may include a plurality of memory holes. A “memory hole,” as used herein, refers to a vertical channel extending two or more physical levels of the substrate. The memory holes may include a vertical trench that is formed to divide one or more memory hole structures into two or more vertical “NOT AND” (NAND) strings. A memory hole may include a vertical channel extending 32 layers, 64 layers, 96 layers, or 112 layers of a substrate. The vertical channels may have a depth of about 2 μm to about 6 μm or more, e.g., about 2 μm, about 3 μm, about 4 μm, or about 5 μm, about 6 μm. The vertical channels may include an aspect ratio of about 1:8 to about 1:160 or more, e.g., about 1:8, about 1:10, about 1:50, about 1:100, about 1:150, or about 1:160.

The plurality of memory holes have a substantially vertical and uniform vertical trench. The plurality of memory holes may comprise one or more vertical features, e.g., necking, clogging, bowing, striations, tapered profiles, underlayer recesses, distortions, tiltings, or twistings. The plurality of memory holes has a first vertical trench comprising a tapered profile extending 16 layers, in which a second vertical trench comprising a tapered profile extends beyond the first vertical trench, creating a shelf.

The plurality of memory holes can include an outer layer within the vertical trench. The outer layer may include a layer of one or more silica substrates, e.g., silicon nitride, or silicon dioxide. For example, and without limitation, the outer layer can be a silicon nitride layer. As a further non-limiting example, the outer layer can be a silicon dioxide layer.

In an embodiment, the present disclosure can be implemented in other technologies having three dimensional patterns including other steps in 3D NAND, or memories such as 3D DRAM that include complex geometries and total exposed surface area 10×-10,000× more than bare silicon wafers.

### Oxidation Process

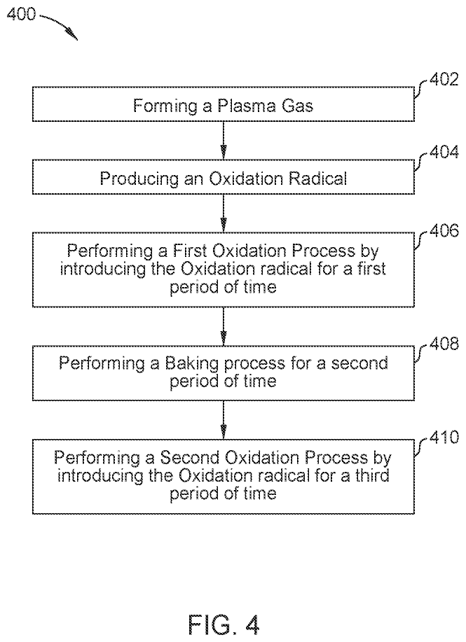

Now referring to FIG. 4, a method 400 of a cyclic growth process is shown. At operation 402, the method includes forming a plasma from a plasma gas using a remote plasma source. Herein, the plasma gas comprises one or more noble gases, such as argon, helium, neon, xenon, krypton, or a combination thereof. For example, and without limitation, the plasma gas is argon. At operation 404, an oxidation radical is produced. In an embodiment, an oxidation radical can be produced by flowing a first gas such as a reactive gas mixture e.g., argon, hydrogen, oxygen, steam or any combination thereof, and a second gas, e.g., a reactive gas such as H₂, O₂, H₂O or a combination thereof, through the plasma remote source to produce radicals of the first gas via interaction with a plasma. The first gas and the second gas can react to form one or more oxidation radicals in the RPS, the processing chamber, or the conduit connecting the RPS and the processing chamber. In an embodiment, an oxidation radical can be produced using one or more of an in situ steam generation module, or other suitable method for producing a radical directly on the substrate.

In an embodiment, producing an oxidation radical may include producing an oxygen radical, hydrogen radical, and/or hydroxyl radical as a function of a reaction between the first gas and the second gas. For example, the hydroxyl radical may be formed as a function of reacting a first gas oxygen with a second gas of hydrogen. The reaction of the first gas and the second gas may result in about 5% to about 20% of products being hydroxyl radical, e.g., about 5%, about 6%, about 7%, about 8%, about 9%, about 10%, about 11%, about 12%, about 13%, about 14%, about 15%, about 16%, about 17%, about 18%, about 19%, or about 20%. A reaction of the first gas and the second gas produces a hydroxide radical in processing chamber when hydrogen gas is more than 50 mol % or vol % present in a H₂:radical-O₂ mixture. For example, a hydroxide radical may be formed when hydrogen gas of a H₂:radical-O₂ mixture is between 50 mol % or vol % and 80 mol % or vol %.

At operation 406, a first oxidation process is performed by introducing the oxidation radical for a first period of time. The first period of time can include about 1 second(s) to about 60 min (min), e.g., about 1 s to about 30 s, about 30 s to about 1 min, about 1 min to about 30 min, or about 30 min to about 60 min. In an embodiment, the first oxidation process can include introducing the oxidation radical to provide a residence time of about 1 min to about 30 min, e.g., about 1 min to about 2 min, about 2 min to about 5 min, about 5 min to about 10 min, about 10 min to about 15 min, about 15 min to about 20 min, about 20 min to about 25 min, or about 25 min to about 30 min. In an embodiment, a lower residence time may increase the conformality of the oxide layer formed on the surface of the memory hole of the substrate.

The first oxidation process can include introducing the oxidation radical, via a plasma conduit, into a processing chamber 100. The processing chamber has a substrate disposed therein. In an embodiment, the first oxidation process can include introducing the oxidation radical while rotating the substrate support on the rotatable cylinder, described above. Rotation of the substrate facilities uniform processing across the substrate.

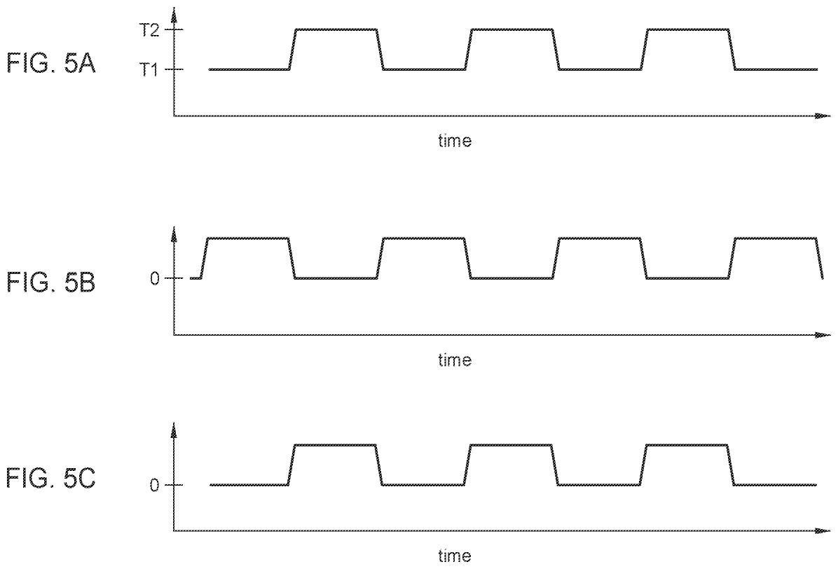

The first oxidation process can include maintaining a first temperature of the processing chamber 100 at about 25° C. to about 900° C., e.g., about 25° C. to about 50° C., about 50° C. to about 100° C., about 100° C. to about 200° C., about 200° C. to about 300° C., or about 300° C. to about 900° C., as shown in FIG. 5A. In an embodiment, the first oxidation process can include introducing the oxidation radical to the processing chamber 100 at a pressure of about 0.1 Torr to about 20 Torr. For example, introducing the oxidation radical can occur while the pressure of the processing chamber is at a reduced pressure of about 1 Torr to about 5 Torr, e.g., about 1 Torr, about 2 Torr, about 3 Torr, about 4 Torr, or about 5 Torr.

The oxidation radicals can be introduced to the processing chamber 100 using a nozzle 163. The nozzle 163 may introduce the oxidation radicals towards the substrate at a volumetric flow rate of about 5 sim to about 200 slm, e.g., about 5 slm to about 20 slm, about 20 slm to about 60 slm, about 60 slm to about 100 slm, about 100 slm to about 150 slm, or about 150 slm to about 200 slm, as shown in FIG. 5B.

The oxidation radicals may be introduced from the nozzle 163 towards the substrate at a gas velocity of about 1 m/s to about 20 m/s, e.g., about 1 m/s, about 2 m/s, about 3 m/s, about 4 m/s, about 5 m/s, about 6 m/s, about 7 m/s, about 8 m/s, about 9 m/s, about 10 m/s, about 11 m/s, about 12 m/s, about 13 m/s, about 14 m/s, about 15 m/s, about 16 m/s, about 17 m/s, about 18 m/s, about 19 m/s, or about 20 m/s. The oxidation radicals may be introduced from the nozzle 163 towards the substrate with enough gas velocity to spread the gases over the substrate.

In an embodiment, first oxidation process can include oxidizing a surface layer of a memory hole of the substrate. Oxidizing the surface layer includes oxidizing a silicon nitride layer to a silicon oxide layer, where the nitrogen may be released from the surface as ammonia and/or NOₓ. For example, the oxidation radical can include a hydroxyl radical that flows into the memory hole to react with the silicon nitride surface of the memory hole of the substrate to form a surface layer of silicon oxide. In an embodiment, the hydroxyl radical may flow into the memory hole to provide greater than 80% conformality, e.g., about 80%, about 85%, about 90%, about 95%, or about 100% conformality.

At operation 408, a baking process is performed in the processing chamber 100. A baking process includes reducing and/or eliminating the flow of the oxidation radical, and concurrently increasing a flow of a bake gas, as shown in FIGS. 5B and 5C. A bake gas can include a reactive gas, e.g., H₂, O₂, or a combination thereof, or an inert gas, e.g., N₂, He, Ar, or a combination thereof. Without being bound by theory, a bake gas including a reactive gas can provide enhanced conformality compared to other gases, e.g., inert gases, and combinations thereof. In an embodiment, the bake gas can be introduced to the processing chamber 100 using the nozzle 163 and/or one or more other nozzles (not shown). The nozzle 163 may introduce the bake gas towards the substrate at a volumetric flow rate of about 5 slm to about 200 slm, e.g., about 5 slm to about 20 slm, about 20 slm to about 60 slm, about 60 sim to about 100 slm, about 100 slm to about 150 slm, or about 150 slm to about 200 sim, as shown in FIG. 5C. Without being bound by theory, the bake gas may include a volumetric flow that removes one or more residual oxidation radicals from the processing chamber, thereby reducing a sticking coefficient, surface roughness, and/or contaminants on the oxide layer.

The bake gas may be introduced from the nozzle 163 and/or one or more other nozzles (not shown) towards the substrate at a gas velocity of about 1 m/s to about 20 m/s, e.g., about 1 m/s, about 2 m/s, about 3 m/s, about 4 m/s, about 5 m/s, about 6 m/s, about 7 m/s, about 8 m/s, about 9 m/s, about 10 m/s, about 11 m/s, about 12 m/s, about 13 m/s, about 14 m/s, about 15 m/s, about 16 m/s, about 17 m/s, about 18 m/s, about 19 m/s, or about 20 m/s. The bake gas may be introduced from the nozzle 163 towards the substrate with enough gas velocity to remove one or more oxidation radicals from the processing chamber 100.

In an embodiment, the bake process can include increasing the temperature of the processing chamber 100 from the first temperature to a second temperature of about 50° C. to about 1100° C., e.g., about 50° C. to about 100° C., about 100° C. to about 200° C., about 200° C. to about 300° C., or about 300° C. to about 1100° C., as shown in FIG. 5A. For example, and without being bound by theory, a second temperature of about 200° C. to about 400° C. can reduce a surface roughness to produce a smooth memory hole surface.

In an embodiment, the bake process can include a temperature ramp rate of about 1° C./min to about 10,000° C./min, e.g., about 1° C./min to about 100° C./min, about 100° C./min to about 500° C./min, about 500° C./min to about 1,000° C./min, about 1,000° C./min to about 5,000° C./min, or about 5,000° C./min to about 10,000° C./min. In an embodiment, a temperature ramp rate of about 5,000° C./min to about 10,000° C./min can increase the conformality of the oxide layer by increasing a surface condition, e.g., reducing a sticking coefficient, reducing a surface roughness, and/or removing one or more contaminants in the oxide layer.

In an embodiment, the bake process can include decreasing the temperature of the processing chamber 100 from the second temperature to the first temperature. In an embodiment, the bake process can include a temperature drop rate of about 1° C./min to about 6000° C./min, e.g., about 1° C./min to about 5° C./min, about 5° C./min to about 10° C./min, about 10° C./min to about 20° C./min, about 20° C./min to about 30° C./min, about 30° C./min to about 40° C./min, about 40° C./min to about 500° C./min, or about 500° C./min to about 6000° C./min. In an embodiment, a temperature drop rate of about 40° C./min to about 60° C./min can increase the conformality of the oxide layer by increasing a surface condition, e.g., reducing a sticking coefficient, reducing a surface roughness, and/or removing one or more contaminants in the oxide layer.

The bake process can include introducing the bake gas from the nozzle 163 and/or one or more other nozzles (not shown) for a second period of time. The second period of time can be the same as the first period of time or different. Without being bound by theory, a first period of time that is different than a second period of time can increase conformality. The second period of time can include about 1 second(s) to about 60 min (min), e.g., about 1 s to about 30 s, about 30 s to about 1 min, about 1 min to about 30 min, or about 30 min to about 60 min. In an embodiment, the bake process can include introducing the bake gas to provide a residence time of about 1 min to about 30 min, e.g., about 1 min to about 2 min, about 2 min to about 5 min, about 5 min to about 10 min, about 10 min to about 15 min, about 15 min to about 20 min, about 20 min to about 25 min, or about 25 min to about 30 min. In an embodiment, a lower residence time may increase the conformality of the oxide layer formed on the surface of the memory hole of the substrate.

In an embodiment, the bake process can include introducing the bake gas to the processing chamber 100 at a pressure of about 0.1 Torr to about 20 Torr. For example, introducing the bake gas can occur while the pressure of the processing chamber is at a reduced pressure of about 1 Torr to about 5 Torr, e.g., about 1 Torr, about 2 Torr, about 3 Torr, about 4 Torr, or about 5 Torr.

At operation 410, performing a second oxidation process by introducing the oxidation radical to the processing chamber. The second oxidation process can include introducing the oxidation radical for a third period of time. The second oxidation process can be similar to the first oxidation process or different.

The oxidation radicals can be introduced to the processing chamber 100 using the nozzle 163 at a volumetric flow rate of about 5 slm to about 200 slm, as described above. The oxidation radicals may be introduced at a gas velocity of about 1 m/s to about 20 m/s, as described above. The first oxidation process can include introducing the oxidation radical from the nozzle 163 for a third period of time. The third period of time can be the same as the first period of time and/or the second period of time, or different. The third period of time can include about 1 second(s) to about 60 min (min), e.g., about 1 s to about 30 s, about 30 s to about 1 min, about 1 min to about 30 min, or about 30 min to about 60 min. In an embodiment, the second oxidation process can include introducing the oxidation radical to provide a residence time of about 1 min to about 30 min, e.g., about 1 min to about 2 min, about 2 min to about 5 min, about 5 min to about 10 min, about 10 min to about 15 min, about 15 min to about 20 min, about 20 min to about 25 min, or about 25 min to about 30 min. In an embodiment, a lower residence time may increase the conformality of the oxide layer formed on the surface of the memory hole of the substrate.

In an embodiment, the second oxidation process can include maintaining the first temperature of the processing chamber 100 at about 25° C. to about 400° C., e.g., about 25° C. to about 50° C., about 50° C. to about 100° C., about 100° C. to about 200° C., about 200° C. to about 300° C., or about 300° C. to about 400° C., as shown in FIG. 5A. In an embodiment, the second oxidation process can include introducing the oxidation radical to the processing chamber 100 at a pressure of about 0.1 Torr to about 20 Torr. For example, introducing the oxidation radical can occur while the pressure of the processing chamber is at a reduced pressure of about 1 Torr to about 5 Torr, e.g., about 1 Torr, about 2 Torr, about 3 Torr, about 4 Torr, or about 5 Torr.

In an embodiment, second oxidation process can include oxidizing a surface layer of a memory hole of the substrate. Oxidizing the surface layer includes oxidizing a silicon nitride layer to a silicon oxide layer, where the nitrogen may be released from the surface as ammonia and/or NOₓ. For example, the oxidation radical can include a hydroxyl radical that flows into the memory hole to react with the silicon nitride surface of the memory hole of the substrate to form a surface layer of silicon oxide. In an embodiment, the hydroxyl radical may flow into the memory hole to provide greater than 80% conformality, e.g., about 80%, about 85%, about 90%, about 95%, or about 100% conformality.

In an embodiment, a second bake process can be performed. The second bake process can be the same as the first bake process or different. For example, the second bake process can include reducing and/or eliminating the flow of the oxidation radical of the second oxidation process, and concurrently increasing a flow of a bake gas, as shown in FIGS. 5B and 5C. The bake gas can include a reactive gas, e.g., H₂, O₂, or a combination thereof, or an inert gas, e.g., N₂, He, Ar, or a combination thereof. The bake gas can be introduced at a volumetric flow rate of about 5 slm to about 200 slm, as shown in FIG. 5C. Without being bound by theory, the a second bake process can removes one or more residual oxidation radicals from the processing chamber, thereby reducing a sticking coefficient, surface roughness, and/or contaminants on the oxide layer. In an embodiment, the second bake process can include increasing the temperature of the processing chamber 100 from the first temperature to the second temperature of about 50° C. to about 400° C., as shown in FIG. 5A. For example, and without being bound by theory, the second temperature of about 200° C. to about 400° C. can reduce a surface roughness to produce a smooth memory hole surface.

In an embodiment the first oxidation process, bake process, and/or second oxidation process can be iteratively cycled until a desired thickness of the oxide layer is reached, as shown in FIGS. 5A-5C. In an embodiment, the method 400 may be iteratively cycled about 2 to about 100 times. For example, the method 400 may be iteratively cycled to include one or more of a second bake process, third oxidation process, third bake process, fourth oxidation process, fourth bake process, fifth oxidation process, fifth bake process, sixth oxidation process, sixth bake process, seventh oxidation process, seventh bake process, eighth oxidation process, eighth bake process, ninth oxidation process, ninth bake process, tenth oxidation process, and/or tenth bake process may be performed. Without being bound by theory, by iteratively cycling the method 400, an increase in conformality of the oxide layer on the surface of the memory hole over conventional oxide layers, which considered oxidation in a single step process, may occur by removing contaminants and lowering the surface roughness, thereby reducing the sticking coefficient during the oxidation process.

### EXAMPLES

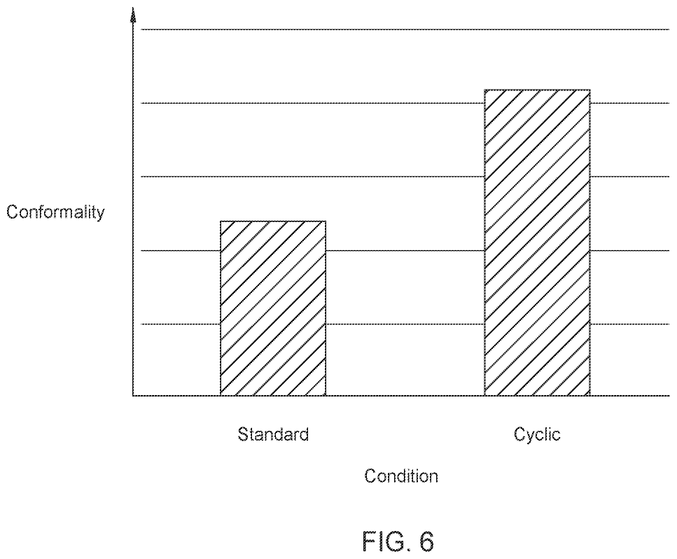

Now referring to FIG. 6, an oxide layer of a substrate formed using a standard oxide layer growth process is compared to an oxide layer formed using a cyclic growth process. The standard oxide layer growth process and the cyclic growth process were both performed for a period of about 5 seconds to about 1 hour, e.g., about 5 seconds to about 30 seconds, about 30 seconds to about 1 minute, about 1 minute to about 30 minutes, or about 30 minutes to about 1 hour. The cyclic growth process resulted in greater conformality due to cycling about 2 iterations to about 100 iterations, e.g., about 2 iterations to about 10 iterations, about 10 iterations to about 20 iterations, about 20 iterations to about 30 iterations, about 30 iterations to about 40 iterations, about 40 iterations to about 50 iterations, about 50 iterations to about 60 iterations, about 60 iterations to about 70 iterations, about 70 iterations to about 80 iterations, about 80 iterations to about 90 iterations, or about 90 iterations to about 100 iterations. Without being bound by theory, the cyclic growth process resulted in greater conformality while operating for the same period of time during growth due to the improved surface properties formed during the cyclic oxidation and bake processes.

Overall, the present disclosure can improve conformality and thickness of an oxide layer formed in a memory hole of a substrate having a high aspect ratio. The system and method can reduce the throughput processing time of oxidation processes by improving one or more memory holes by reducing a surface property, e.g., stickiness, roughness, and/or concentration of contaminants. The iterative cycling, implementing a baking process between oxidation processes, can improve the surface condition to enable more conformal growth by reducing the sticking coefficient, allowing more reactants to reach the bottom of the memory hole. Moreover, the surface roughness is reduced and the concentration of film contaminants is reduced using the cyclic growth process, allowing for uniform growth of the oxide layer on the substrate surface, increasing conformality.

While the foregoing is directed to embodiments of the disclosure, other and further embodiments may be devised without departing from the basic scope thereof, and the scope thereof is determined by the claims that follow.

1. A method of performing a cyclic growth oxidation process, comprising;
producing an oxidation radical;
performing a first oxidation process in a processing chamber by introducing the oxidation radical for a first period of time to the processing chamber using a first nozzle;
performing a bake process for a second period of time; and
performing a second oxidation process by introducing the oxidation radical for a third period of time.

2. The method of claim 1, wherein the first oxidation process comprises a volumetric flow of about 5 standard liters per minute (sim) to about 40 slm.

3. The method of claim 1, wherein the first oxidation process comprises a first temperature of about 25° C. to about 900° C.

4. The method of claim 3, wherein the bake process comprises a second temperature of about 50° C. to 1100° C.

5. The method of claim 4, wherein the bake process further comprises increasing the first temperature to the second temperature at a rate of about 1° C. per minute (° C./min) to about 10,000° C./min.

6. The method of claim 4, wherein the bake process further comprises dropping the second temperature to the first temperature at a rate of about 1° C./min to about 6000° C./min.

7. The method of claim 1, further comprises introducing a bake gas to the processing chamber.

8. The method of claim 7, wherein introducing the bake gas comprises a volumetric flow rate of about 5 slm to about 200 slm of the bake gas.

9. The method of claim 1, wherein the first period of time, the second period of time, and the third period of time are the same.

10. The method of claim 1, wherein the first period of time, the second period of time, and the third period of time are different.

11. The method of claim 1, further comprising iteratively cycling the method about 2 to about 100 times.

12. A substrate processing system, comprising:
a processing chamber;
a conduit coupled to a first nozzle of the processing chamber, wherein the first nozzle is coupled to a first gas source;
a controller configured to:
produce an oxidation radical using the first gas source;
perform a first oxidation process by introducing the oxidation radical for a first period of time to the processing chamber using the first nozzle;
perform a bake process for a second period of time by introducing a bake gas to the processing chamber using the first nozzle; and
perform a second oxidation process by introducing the oxidation radical for a third period of time to the processing chamber using the first nozzle.

13. The system of claim 12, wherein the oxidation radical comprises a hydrogen radical, oxygen radical, or hydroxide radical.

14. The system of claim 13, wherein the oxidation radical comprises a hydroxide radical.

15. The system of claim 12, wherein the processing chamber comprises a pressure of about 0.1 Torr to about 20 Torr.

16. The system of claim 12, wherein the first nozzle introduces the oxidation radical or the bake gas at a volumetric flow of about 5 slm to about 200 slm.

17. The system, of claim 12, wherein the first oxidation process comprises a first temperature of about 25° C. to about 900° C.

18. The system of claim 17, wherein the bake process comprises a second temperature of about 50° C. to about 1100° C.

19. The system of claim 12, wherein the first period of time, the second period of time, and the third period of time are the same or different.

20. A computer readable medium configured to:
produce an oxidation radical using a first gas;
perform a first oxidation process by introducing the oxidation radical for a first period of time to a processing chamber using a first nozzle;
perform a bake process for a second period of time by introducing a bake gas to the processing chamber using the first nozzle and increasing a temperature of the processing chamber; and
perform a second oxidation process by introducing the oxidation radical for a third period of time to the processing chamber using the first nozzle.
